(19) United States
(12) Patent Application Publication
(10) Pub. No.: US 2018/0264590 A1
(43) Pub. Date: Sep. 20, 2018

(54) IN SITU ADDITIVE MANUFACTURING PROCESS SENSING AND CONTROL INCLUDING POST PROCESS NDT

(71) Applicant: JENTEK Sensors, Inc., Marlborough, MA (US)

(72) Inventors: Neil J. Goldfine, Cocoa Beach, FL (US); Zachary M. Thomas, Pittsburgh, PA (US); Todd M. Dunford, Amherst, MA (US)

(73) Assignee: JENTEK Sensors, Inc., Marlborough, MA (US)

(21) Appl. No.: 15/922,889

(22) Filed: Mar. 15, 2018

Related U.S. Application Data
(60) Provisional application No. 62/471,447, filed on Mar. 15, 2017.
(60) Provisional application No. 62/632,164, filed on Feb. 19, 2018.

(51) Int. Cl. B23K 26/042; G01K 13/00; G01R 19/00; B22F 3/105; B33Y 10/00; B33Y 30/00; B33Y 50/02; B23K 26/03; B23K 15/00

(52) U.S. Cl. CPC B23K 26/042; G01K 13/00; G01R 19/0046; B22F 3/1055; B22F 2003/1057; B33Y 30/00; B33Y 50/02; B23K 26/034; B23K 15/0086; B33Y 10/00

(57) ABSTRACT

A sensor is provided near an additive manufacturing (AM) part during fabrication to provide information about the condition of the additive material during fabrication. Sensor measurements are used for in situ monitoring and control of the AM system. By placing a sensor at this location, information at or near this location may be collected and then analyzed to determine if the AM process is proceeding acceptably, or if real-time modifications to the process should be made to improve the performance of the process. Conditions monitored by the sensor may include the melt pool dimensions, the temperature ahead of and at the melt pool, properties of the powder bed such as temperature and particle size distribution, local powder conditions, prior layer condition, and applied layer condition behind the laser. A control system uses these monitored conditions to adjust and control the ongoing AM fabrication process.

The present application claims priority under 35 U.S.C. § 119(e) to U.S. provisional patent application, U.S. Ser. No. 62/471,447, filed Mar. 15, 2017 and U.S. provisional patent application, U.S. Ser. No. 62/632,164, filed Feb. 19, 2018, both of which are herein incorporated by reference in its entirety.

### BACKGROUND

Additive manufacturing (AM) is a manufacturing approach for components in which material is built upon through a sintering or similar process. This is in contrast with traditional manufacturing approaches such as machining, where material is primarily removed to fabricate a component. It is highly desirable that AM technologies be matured so that this manufacturing technique can be expanded to more items such as fatigue critical metal components that require high quality and no significant defects that degrade fatigue damage tolerance. AM has numerous potential advantages over existing technologies. To list but a few, AM provides few design constraints, the machine requirements can be relatively generic so that parts could be fabricated anywhere, reducing tooling requirements drastically reduces factory set-up time, and old parts can be replaced with identical or nearly identical parts even if the original tooling is no longer available.

Fracture critical components, such as rotating components in jet and land based turbines, would particularly benefit from an AM capability. At this time, however, AM parts still require several trial and error runs with post-processing heat treatments and machining to optimize the build, reduce residual stresses, and meet tolerances. One of the reasons for the lack of a stable AM process is the inherent variabilities at all steps (pre-, in-, and post-processing) of the AM process which tend to produce parts with inconsistent tolerances, mechanical properties, and defects.

Powder bed fusion (PBF) systems utilize a powder material source. The powder is sintered by a laser to build solid objects. Fabrication is performed layer by layer. A rake or roller distributes a prescribed layer of powder over a built platform. The laser sinters the powder at selected locations on the layer. After completing sintering of the layer a new layer of powder is applied by rake/roller. The new layer is appropriately sintered by the laser. The process is repeated until the desired object is complete. The work product is removed from the loose, unfused powder that was not sintered by the laser. A build plan specifies exactly what areas of each layer are to be sintered by the laser so that the desired object is produced.

Directed energy deposition (DED) uses a focused energy beam and a system to deliver a powder or wire in to a molten pool on a substrate surface.

E-Beam welding is another approach that adds material to fabricate a part using an electron beam to perform the processing. Other welding methods and coating methods such as cold spray can also be considered as additive and all such methods can be used for both original part fabrication and for repair or reworking of parts after removal of defective areas.

### SUMMARY

Some aspects relate to an additive manufacturing (AM) system for producing an AM part, the system comprising: a laser; a build platform; a sensor with a drive winding having a linear portion and a linear array of sense windings a constant distance from the linear portion of the drive winding; a sensor positioning system to position the sensor between the laser and the build platform; an instrument to monitor a response of the sensor during an additive manufacturing process; and a control system configured to control the laser and the sensor positioning system based at least in part on the response of the sensor.

In some embodiments the sensor has an open space between the linear portion of the drive winding and the linear array of sense windings, and the control system is configured to control the laser and the sensor positioning system to focus the laser in the open space during the additive manufacturing process.

In some embodiments each of the sense windings in the linear array have a rectangular winding portion and leads thereto, and the instrument excites a current at a frequency and measures the response of the sensor at each sense winding in the linear array at said frequency.

In some embodiments the linear array of sense windings is a first linear array and the sensor further comprises a second linear array of sense windings at a second constant distance from the linear portion of the drive winding, and the instrument measures the response of the sensor at each sense winding in the first linear array and each sense winding in the second linear array.

In some embodiments comprising an analysis module to determine, based at least in part on the response of the sensor, a quality of the AM part.

In some embodiments an optimal sensor, wherein the analysis module determines the quality of the AM part based at least in part on a response of the optical sensor.

In some embodiments the control system determines a property of the melt pool from the sensor response and controls the laser and the sensor positioning system based at least in part on the property of the melt pool.

In some embodiments wherein the property is temperature.

Another aspect relates to a method of additively manufacturing (AM) an AM part, the method comprising: providing a powder bed on a build platform; providing a sensor in a noncontact mode above the powder bed, the sensor having a drive winding with a linear portion and a linear array of sense windings a constant distance from the linear portion of the drive winding; directing a laser at a location on the powder bed through an open space in the sensor; exciting a current at a frequency in the drive winding; measuring a response of the sensor to the current; and redirecting the laser and controlling the position of the sensor based at least in part on the response of the sensor.

In some embodiments providing the powder bed comprises depositing a plurality of powder layers, the powder layers including a surface layer and a subsurface layer, the method further comprising: determining from the response of the sensor a first property of the surface layer and a second property of the subsurface layer in the powder bed.

In some embodiments providing the powder bed comprises depositing a plurality of powder layers, the powder layers including a surface layer, and the penetration depth at the frequency of the drive current is greater than a thickness of the surface layer but less than three times the thickness of the surface layer.

In some embodiments providing the powder bed comprises depositing a plurality of powder layers, the powder layers including a surface layer and a subsurface layer, the frequency is a first frequency and the current is also excited at a second frequency, the response of the sensor is measured at both the first and second frequencies, and the method further comprises determining at least three properties of the powder bed, at least one of the properties being of the surface layer and at least another one of the properties being of the subsurface layer.

In some embodiments the at least three properties comprise a liftoff of the sensor from the powder bed, a conductivity of the surface layer, and a conductivity of the subsurface layer.

Another aspect relates to an additive manufacturing (AM) system for producing an AM part, the system comprising: an energizing element for sintering an AM feed stock; an eddy current sensor; an instrument to monitor a response of the eddy current sensor during sintering; and a control system configured to control the energizing element based at least in part on the response of the eddy current sensor.

In some embodiments the eddy current sensor is an eddy current array sensor having a drive winding with a linear portion and a linear array of sense windings a constant distance from the linear portion of the drive winding.

Some embodiments further comprise a sensor positioning system for positioning the eddy current array sensor, wherein the control system additionally controls a position of the sensor positioning system based at least in part on the response of the eddy current array sensor.

In some embodiments the energizing element is a laser. In some embodiments the energizing element is an electron beam.

Some embodiments further comprise: a build platform; and a powder distributor for distributing a layer of powder over the build platform, wherein the eddy current sensor is an eddy current sensor array mechanically attached to the powder distributor.

Another aspect relates to A system configured for in process monitoring of a melt pool or weld site. In some embodiments the process monitoring is in process layer by layer NDT following the rake or integrated with the rake or other means for scanning the surface noncontact between layer deposition steps. Some embodiments comprise a processor to perform post process NDT before and after post processing using hipping or other means to change porosity.

Some embodiments are configured to perform post process NDT using knowledge that the process was performed using AM, such as layering to identify representative defect types. Using this to select the frequency, drive orientation, and/or to provide feedback to the processing to improve quality.

Some embodiments are configured to perform post process NDT to identify linear defects, local defects and gradual material variations and attributing these to AM processing issues and iteratively improving the process to eliminate these defects.

Some embodiments are configured to perform post process NDT for part qualification using segmented field MWM-Arrays or just MWM-Arrays and possibly adding knowledge of specific AM defect types is unique.

Another aspect relates to an apparatus for nondestructive testing of an additive manufactured part, including: an eddy current sensor array and a model that enables correction of data for variable liftoff and provides a measure of density by correlating electrical conductivity measurements with porosity a part using a set of standards to build the correlation for essentially the same process setup. Local high porosity regions may be detected. Linear porosity defects may be detected. Gradual variations in porosity may be mapped with a C-scan imaging software tool. The results of the NDT may be used to improve the process to reduce the occurrence of the detected defects. A precomputed database may be used to provide the multiple unknown property estimation. Scans with two drive conductor orientations may be made and combined to enable detection of more defect types more reliably.

Another aspect relates to an apparatus with an eddy current sensor array including a linear drive and at least two sensing elements at a prescribed distance from the drive for non-contact imaging of a material during additive manufacturing where the array response is used to characterize both the processed material in solid form and the powder material using at least two frequencies where one frequency is sufficiently high to induce eddy currents in the powder and the other frequency is less than 5 MHz. The powder may be non-magnetic and the measurement is sensitive to the conductivity and size of powder and conductivity variation in the solid. The powder may be magnetic and a low frequency below 10 KHz is used to measure a magnetic property and a high frequency above 100 KHz is used to determine the electrical conductivity and the two frequencies together are used to estimate particle size. At least two frequencies may be used to estimate particle size variations. At least two frequencies may be used to detect clumping or other anomalies in the powder. The array response may be used to determine the temperature of the powder. The array response may be used to determine the temperature of the solid.

The foregoing is a non-limiting summary of the invention, which is defined by the attached claims.

### BRIEF DESCRIPTION OF DRAWINGS

The accompanying drawings are not intended to be drawn to scale. In the drawings, each identical or nearly identical component that is illustrated in various figures is represented by a like numeral. For purposes of clarity, not every component may be labeled in every drawing. In the drawings:

FIG. 1 is an overview of a system for taking and processing sensor measurements according to some embodiments;

FIGS. 2A and 2B are a block diagram of an additive manufacturing system having an in situ sensor and control system according to some embodiments;

FIG. 3A-3C are example sensor embodiments;

FIG. 4 illustrates laser beam and sensor motion according to some embodiments; and

FIG. 5 is a flow diagram for in situ additive manufacturing process sensing and control according to some embodiments.

### DETAILED DESCRIPTION

The inventors have recognized and appreciated the need for improved monitoring and control of the AM process, as well as the need for effective non-destructive inspection of AM components during the AM process. A sensor may be provided near the AM part during fabrication to provide information about the condition of the additive material during fabrication. For example, during PBF AM manufacturing, a sensor may be disposed near where the laser beam sinters the powder bed. By placing a sensor at this location, information at or near this location may be collected and then analyzed to determine if the AM process is proceeding acceptably, or if real-time modifications to the process should be made to improve the performance of the process. One sensor contemplated for such monitoring is an eddy current sensor such as the MWM-Array sensor technology. The impedance measurements of an eddy current sensor array may be used to determine the melt pool dimensions, the temperature ahead of the melt pool and at the melt pool, the powder bed (smoothness, height, temperature, particle size distribution, density) and local powder (clumping, splatter, particle size, voids, contamination, non-powder material) condition ahead of the laser beam, prior layer condition, and applied layer condition behind the laser, including local defect characterization and layer quality. These in turn could be used to adjust the AM fabrication process. This includes not only properties at the surface but also subsurface and as a function of depth.

Sensor monitoring may take place at other locations away from the melt pool such as over the surface of the powder bed. In some embodiments a sensor is used to scan across the exposed surface after each layer is applied. This scan could take place immediately before or after sintering of the layer. In a PBF system, for example, a sensor may be integrated into the new layer deposition system to perform such a scan immediately following the laser pattern across the part. In another such embodiment the sensor could be integrated with and proceed or follow a rake or roller. Proceeding the roller would enable scanning of the last AM processed layer for quality, condition and defects. Following would enable quality assessment of the powder layer. One sensor that may be used is an eddy current array. This “global” monitoring capability may be used to identify anomalies in the AM fabrication process. This information could be used to improve the laser beam application process for subsequent sintering of the powder bed material.

Also, this information could be used to prompt the AM processing machine to revisit a location and perform an in-process rework to remove a defect or inconsistency. This global monitoring can provide not only local material and layer assessments but also geometric assessments and verification of dimensions for each layer. For eddy current sensing multiple frequencies can also be used to provide material and geometric property variations with depth. Also subpixel geometric assessment is possible with training prior to processing on test samples. This geometric assessment (global, local and subpixel) has been demonstrated on static final components and is included hear to describe use of this method for holes, and other complex and simple geometric features during processing for each layer.

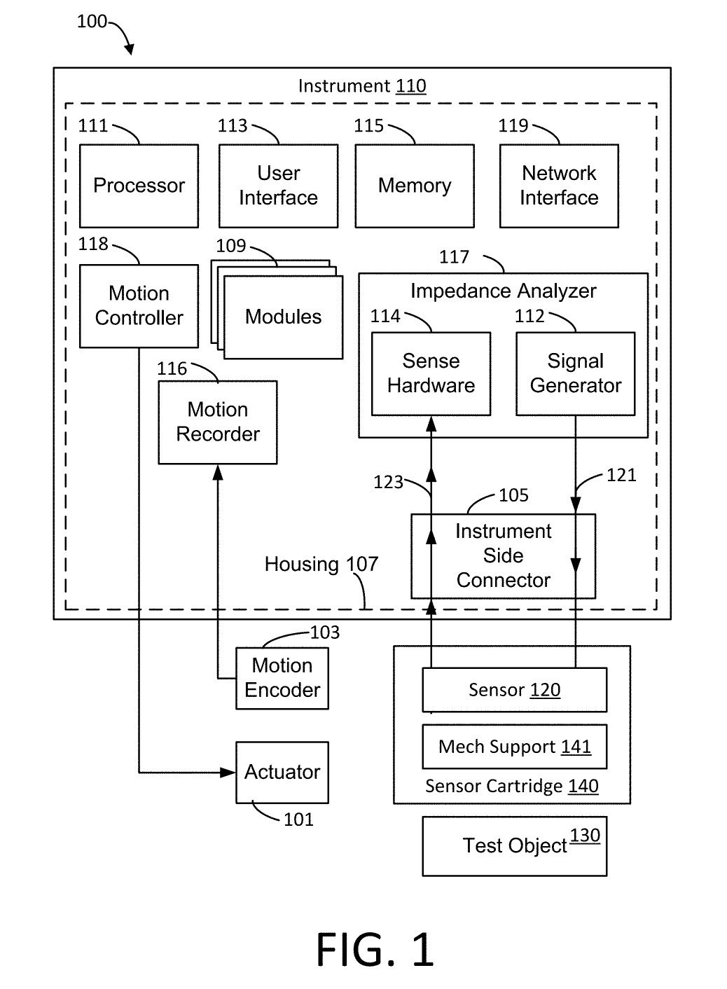

FIG. 1 is a block diagram of a system 100 for inspecting a test object 130. System 100 includes an instrument 110 and a sensor cartridge 140. Instrument 110 may be housed in a housing 107; in some embodiments the housing is substantially cylindrical in shape. Sensor cartridge 140 has a rigid connector which interfaces both mechanically and electrically with an instrument side connector 105. Advantageously in some embodiments both the electrical and mechanical connections of sensor cartridge 140 engage simultaneously with connector 105. Sensor cartridge 140 in some embodiments also includes a flexible sensor 120, and a mechanical support 141 to which the sensor is attached. In other embodiments the sensor cartridge includes a rigid sensor held parallel to the test object at an approximately fixed distance. In one such embodiment different sensor array geometries are available for different part geometries and sizes with a convenient mechanism for changing of the sensor cartridges by the operator. Instrument 110 is configured to provide excitation signals 121 to sensor 120 and measure the resulting response signals 123 of sensor 120. Response signals 123 may be measured and processed to estimate properties of interest, such as electromagnetic properties (e.g., conductivity, permeability, and permittivity), geometric properties (e.g., layer thickness, sensor lift-off), material condition (e.g., fault/no fault, crack size, layer to layer bond integrity, residual stress level, temperature), or any other suitable property or combination thereof including properties of the fabricated part and the powder. (Sensor lift-off is a distance between the sensor and the closest surface of the test object for which the sensor is sensitive to the test object's electrical properties.)

Instrument 110 may include a processor 111, a user interface 113, memory 115, an impedance analyzer 117, and a network interface 119. Though, in some embodiments of instrument 110 may include other combinations of components. While instrument 110 is drawn with housing 107, it should be appreciated that instrument 110 may be physically realized as a single mechanical enclosure; multiple, operably-connected mechanical enclosures, or in any other suitable way. For example, in some embodiments it may be desired to provide certain components of instrument 110 as proximal to sensor 120 as practical, while other components of instrument 110 may be located at greater distance from sensor 120.

Processor 111 may be configured to control instrument 110 and may be operatively connected to memory 115. Processor 111 may be any suitable processing device such as for example and not limitation, a central processing unit (CPU), digital signal processor (DSP), controller, addressable controller, general or special purpose microprocessor, microcontroller, addressable microprocessor, programmable processor, programmable controller, dedicated processor, dedicated controller, or any suitable processing device. In some embodiments, processor 111 comprises one or more processors, for example, processor 111 may have multiple cores and/or be comprised of multiple microchips. Processing of sensor data and other computations such as for control may be performed sequentially, in parallel, or by some other method or combination of methods.

Memory 115 may be integrated into processor 111 and/or may include “off-chip” memory that may be accessible to processor 111, for example, via a memory bus (not shown). Memory 115 may store software modules that when executed by processor 111 perform desired functions. Memory 115 may be any suitable type of non-transient computer-readable storage medium such as, for example and not limitation, RAM, a nanotechnology-based memory, one or more floppy disks, compact disks, optical disks, volatile and non-volatile memory devices, magnetic tapes, flash memories, hard disk drive, circuit configurations in Field Programmable Gate Arrays (FPGA), or other semiconductor devices, or other tangible, non-transient computer storage medium.

Instrument 110 may have one or more functional modules 109. Modules 109 may operate to perform specific functions such as processing and analyzing data. Modules 109 may be implemented in hardware, software, or any suitable combination thereof. Memory 115 of instrument 110 may store computer-executable software modules that contain computer-executable instructions. For example, one or more of modules 109 may be stored as computer-executable code in memory 115. These modules may be read for execution by processor 111. Though, this is just an illustrative embodiment and other storage locations and execution means are possible.

Instrument 110 provides excitation signals for sensor 120 and measures the response signal from sensor 120 using impedance analyzer 117. Impedance analyzer 117 may contain a signal generator 112 for providing the excitation signal to sensor 120. Signal generator 112 may provide a suitable voltage and/or current waveform for driving sensor 120. For example, signal generator 112 may provide a sinusoidal signal at one or more selected frequencies, a pulse, a ramp, or any other suitable waveform. Signal generator may provide digital or analog signals and include conversion from one such mode to another.

Sense hardware 114 may comprise multiple sensing channels for processing multiple sensing element responses in parallel. For sensors with a single drive and multiple sensing elements such as the MWM-Array the sensing element response may be measured simultaneously at one or multiple frequencies including simultaneous measurement of real and imaginary parts of the transimpedance. Though, other configurations may be used. For example, sense hardware 114 may comprise multiplexing hardware to facilitate serial processing of the response of multiple sensing elements and for eddy current arrays other than MWM-Arrays multiplexing may be used for combinations of sensing elements and drive elements. Some embodiments use MWM-Array formats to take advantage of the linear drive and the ability to maintain a consistent eddy current pattern across the part using such a linear drive. Sense hardware 114 may measure sensor transimpedance for one or more excitation signals at on one or more sense elements of sensor 120. It should be appreciated that while transimpedance (sometimes referred to simply as impedance), may be referred to as the sensor response, the way the sensor response is represented is not critical and any suitable representation may be used. In some embodiments, the output of sense hardware 114 is stored along with temporal information (e.g., a time stamp) to allow for later temporal correlation of the data, and positional data correlation to associate the sensor response with a particular location on test object 130.

Sensor 120 may be an eddy-current sensor, a dielectrometry sensor, an ultrasonic sensor, thermography method, or utilize any other suitable sensing technology or combination of sensing technologies. In some embodiments sensor 120 provides temperature measurement, voltage amplitude measurement, stain sensing or other suitable sensing modalities or combination of sensing modalities. In some embodiments, sensor 120 is an eddy-current sensor such as an MWM®, MWM-Rosette, or MWM-Array sensor available from JENTEK Sensors, Inc., Marlborough, Mass. Sensor 120 may be a magnetic field sensor or sensor array such as a magnetoresistive sensor (e.g., MR-MWM-Array sensor available from JENTEK Sensors, Inc.), a segmented field MWM sensor, hall effect sensors, and the like. In another embodiment, sensor 120 is an interdigitated dielectrometry sensor or a segmented field dielectrometry sensor such as the IDED® sensors also available from JENTEK Sensors, Inc. Segmented field sensors have sensing elements at different distances from the drive winding or electrode to enable interrogation of a material to different depths at the same drive input frequency. Sensor 120 may have a single or multiple sensing and drive elements. Sensor 120 may be scanned across, mounted on, or embedded into test object 130.

In some embodiments, the computer-executable software modules may include a sensor data processing module, that when executed, estimates properties of test object 130. The sensor data processing module may utilize multi-dimensional precomputed databases that relate one or more frequency transimpedance measurements to properties of test object 130 to be estimated. The sensor data processing module may take the precomputed database and sensor data and, using a multivariate inverse method, estimate material properties for the processed part or the powder. Though, the material properties may be estimated using any other analytical model, empirical model, database, look-up table, or other suitable technique or combination of techniques.

User interface 113 may include devices for interacting with a user. These devices may include, by way of example and not limitation, keypad, pointing device, camera, display, touch screen, audio input and audio output.

Network interface 119 may be any suitable combination of hardware and software configured to communicate over a network. For example, network interface 119 may be implemented as a network interface driver and a network interface card (NIC). The network interface driver may be configured to receive instructions from other components of instrument 110 to perform operations with the NIC. The NIC provides a wired and/or wireless connection to the network. The NIC is configured to generate and receive signals for communication over network. In some embodiments, instrument 110 is distributed among a plurality of networked computing devices. Each computing device may have a network interface for communicating with other the other computing devices forming instrument 110.

In some embodiments, multiple instruments 110 are used together as part of system 100. Such systems may communicate via their respective network interfaces. In some embodiments, some components are shared among the instruments. For example, a single computer may be used control all instruments. In one embodiment multiple areas on the test object are scanned using multiple sensors simultaneously or in an otherwise coordinated fashion to use multiple instruments and multiple sensor arrays with multiple integrated connectors to inspect the test object surface faster or more conveniently.

Actuator 101 may be used to position sensor cartridge 140 with respect to test object 130 and ensure that the liftoff of the sensor 120 is in a desired range relative to the test object 130. Actuator 101 may be an electric motor, pneumatic cylinder, hydraulic cylinder, or any other suitable type or combination of types of actuators for facilitating movement of sensor cartridge 140 with respect to test object 130. Actuators 141 may be controlled by motion controller 118. Motion controller 118 may control sensor cartridge 140 to move sensor 120 relative to test object 130.

Regardless of whether motion is controlled by motion controller 118 or directly by the operator, position encoders 143 of fixture 140 and motion recorder 116 may be used to record the relative positions of sensor 120 and test object 130. This position information may be recorded with impedance measurements obtained by impedance instrument 117 so that the impedance data may be spatially registered.

Some further embodiments of system 100 are disclosed in U.S. patent application Ser. No. 15/030,094 filed Apr. 18, 2016 (U.S. published application No. 2016/0274060) which is hereby incorporated by reference in its entirety.

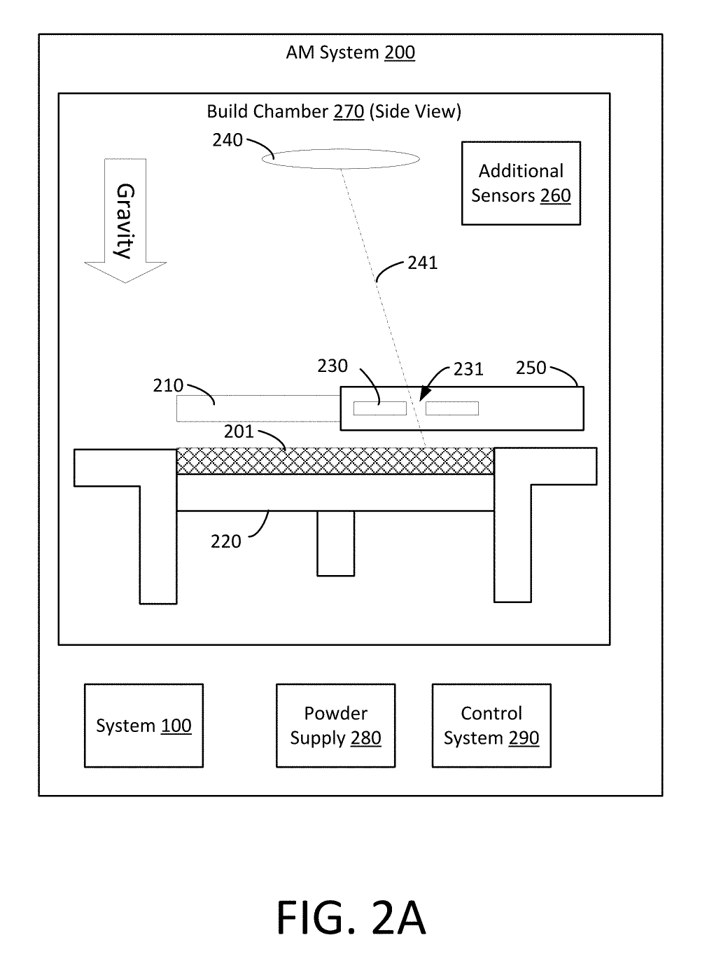

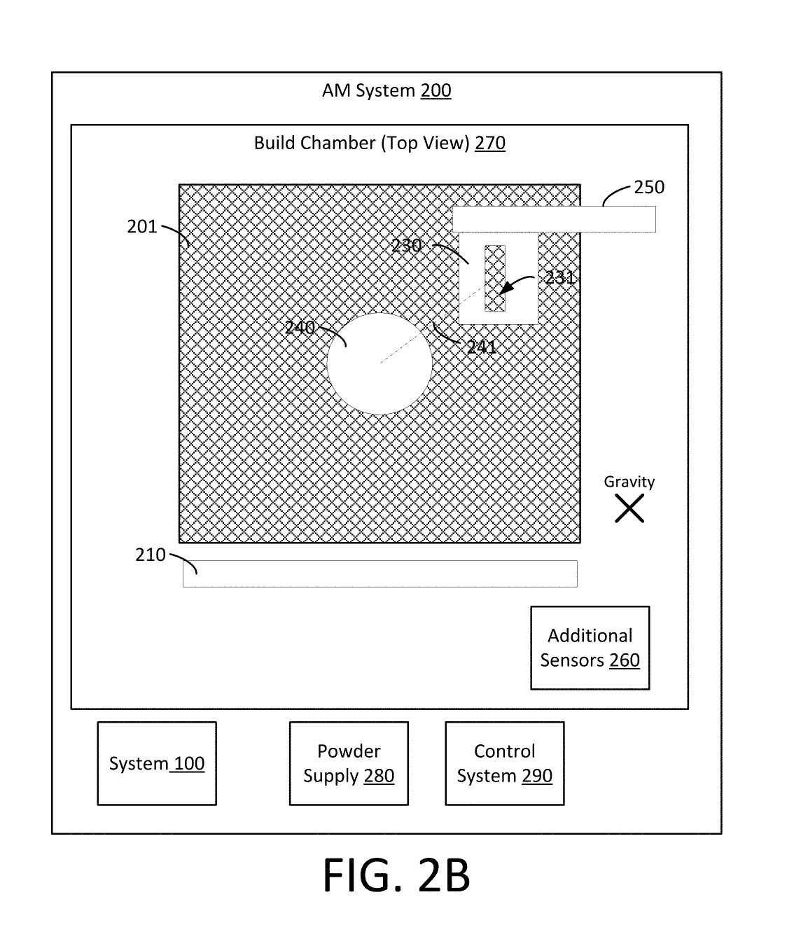

FIGS. 2A and 2B show a block diagram of AM system 200 which uses a sensor 230 and a control system 290 according to some embodiments. While here system 200 is described for a powder bed fusion (PBF) system, it should be appreciated that other embodiments may utilize other AM fabrication techniques such as E-beam, DED or other AM technologies.

System 200 has a build chamber 270, a powder supply 280, a build platform 220, a rake/roller 210, a laser 240, a sensor 230, a sensor positioning system 250, and a control system 290. Additionally system 200 may include aspects of system 100 which was previously described in connection with FIG. 1.

FIG. 2A shows a side view of build chamber 270 and the components therein with gravity in the downward direction. FIG. 2B shows a top view of build chamber 270 and the components therein with gravity in the direction into the page. It is noted that system 100, additional sensors 260, powder supply 280, and control system 290 are simply represented as block diagram elements in AM system 200 while the remaining elements may have at least some aspect of the relative physical position represented by the figures in a way that is relevant to some embodiments.

System 200 is depicted during a fabrication of an AM part. As depicted in FIGS. 2A and 2B, a powder bed 201 is partially built up. Also laser 240 is show exciting laser beam 241.

Build chamber 270 is a volume of space in which AM system 200 builds AM parts. In some embodiments build chamber may be open to the surrounding environment. In some other embodiments build chamber 270 is sealed. In sealed embodiments, build chamber 270 may be under vacuum or partial vacuum, filled with a gas other than air (e.g., an inert gas), or both.

Powder supply 280 is a reservoir of powder material that will be used to fabricate the AM part. Powder supply 280 is designed to facilitate deliver of powder to rake/roller 210 or to another powder delivery mechanism as may be used in other embodiments (e.g., a powder delivery nozzle). Powder supply 280 may use gravity feed, a screw system, and/or a suitable powder moving technology to provide powder to the delivery mechanism. Powder supply 280 may store any suitable powder type. Metal part fabrication powders are available for Ti64, 316L SS, Inconel 625, and a variety of metal alloys. In other embodiments powders other than metal part fabrication powders may be used.

Rake/roller 210 is a delivery mechanism for distributing powder in layers over build platform 220. The thickness of the powder layer may be specified by the build plan or specific to the capabilities of the particular system embodiment. A typical layer thicknesses is 0.01 mm to 0.1 mm, though any suitable layer thickness may be used.

Build platform 220 provides a temporary substrate for fabrication of the AM part. Build platform 220 may lower in the gravity direction and away from laser 240 so that the relative position of the surface of powder bed 201 and laser 240 is consistent.

Laser 240 provides energy in the form of radiation (via laser beam 241) which is absorbed by a selected portion of powder bed 201. The material at the selected location is sintered. The laser is controlled to move to various positions on the surface of powder bed 201. Once sintering has been performed at all locations on the current layer of powder bed 201, if additional layers are required the next layer is delivered by rake/roller 210 and the sintering process continues.

Sensor positioning system 250 positions sensor 230 such that laser beam 241 of laser 240 sinters an area of powder bed 201 that sensor 230 is sensitive to. Sensor positioning system 250 may provide sufficient movement of sensor 230 so that regardless of where laser beam 241 is focused on powder bed 201, sensor 230 may be appropriately positioned to capture the desired measurements. System 100, discussed in connection with FIG. 1, may be used to obtain measurements from sensor 230. Further sensor positioning system 250 may be implemented in ways described in connection actuator 101, motion encoder 103, motion controller 18, and motion recorder 116 of system 100. Sensor 230 may be mounted to positioning system 250 at a relatively fixed non-zero distance from powder bed 201. Such a noncontact configuration prevents sensor 230 from disturbing powder bed 201. This lift-off distance may be measured by sensor 230 to insure that measurements of powder bed 201 are not erroneous due to the presence of this gap. In embodiments where sensor 230 measures this distance the accuracy of sensor positioning system 250 in providing a consistent lift-off distance becomes less important and more tolerance is acceptable.

Sensor 230 may have an open space 231 that allows laser beam 241 to pass through. Because sensor 230 is close to laser beam 241 and the melt pool, it may be subject to high temperatures than would not be required if measurements were being taken at room temperature. In some embodiments sensor 230 is made out of ceramic materials and other temperature tolerant materials to ensure operation despite the high operating temperature.

In some embodiments a splash guard is mounted to sensor 230 or sensor positioning system 250 in order to prevent damage to sensor 230 as well as interference with the measurements performed by sensor 230. The splash guard may prevent or reduce the amount of debris from the laser sintering process that hits or lands on the sensor. A tool may periodically clear or wipe the splash guard. For example, the tool may be like a windshield wiper that moves back and forth occasionally. Alternatively a continuously rotating and self-replacing splash guard might be included to clear residue and protect the sensor, while also preventing spatter from hitting the powder bed ahead of the processing.

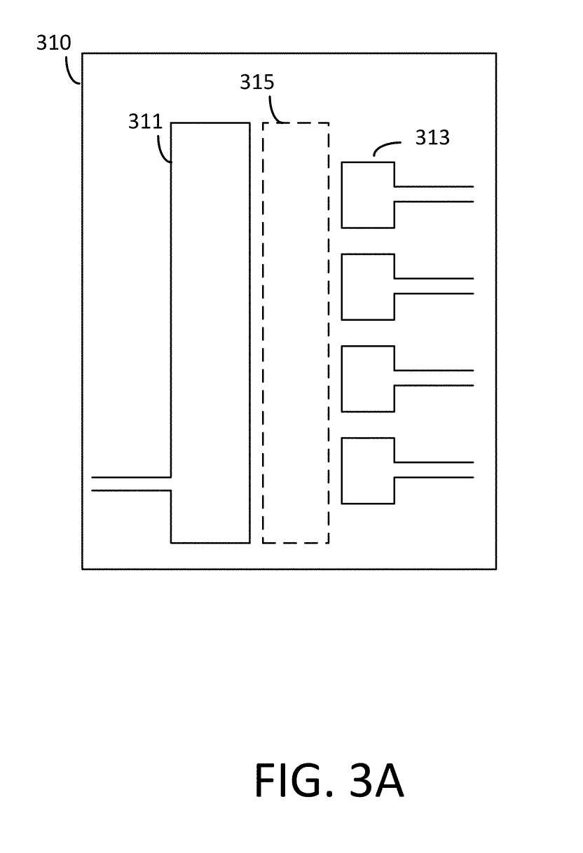

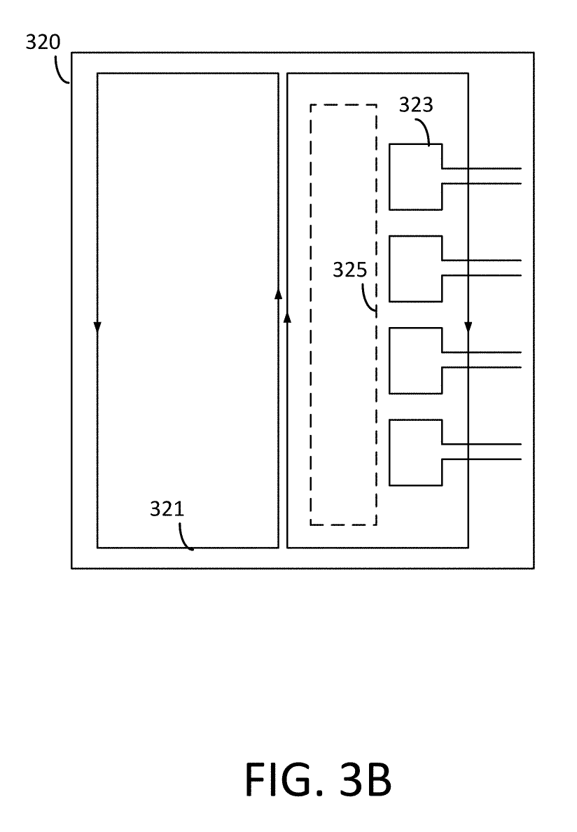

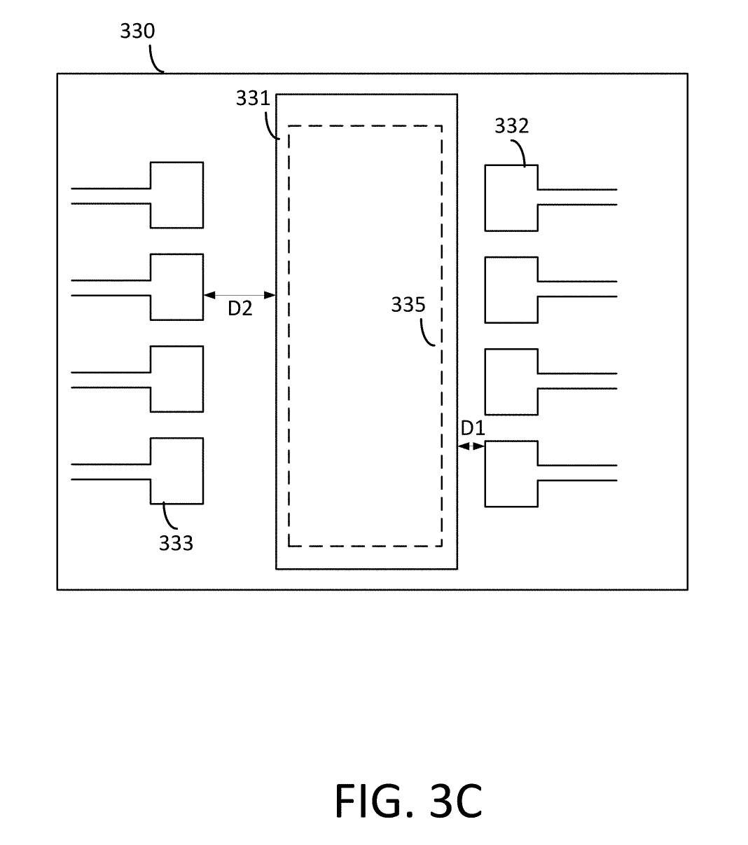

Further embodiments of sensor 230 are described below in connection with FIGS. 3A-3B.

Laser 240 and sensor positioning system 250 are controlled by control system 290. Control system 290 receives input in the form of a build plan for the AM part and through measurements from sensor 230 and potentially additional sensors 260. In some embodiments system 200 includes additional sensors 260 that may be used to provide additional information to control system 290. Control system 290 outputs control signals to all controllable aspects of the process. These aspects include controlling laser 240's power level, position and path, speed, and any other controlled parameters of laser 240. Control system 290 also provides position, path, and speed control signals to sensor positioning system 250. Other aspects of system 200 that may be controlled by control system 290 include control of powder and part temperature, the position and orientation of the AM part (e.g., the height of build platform 220). Each of these recipients of control signals (or control commands) is configured to respond to the control signals to adjust the AM process in the desired manner. In one such embodiment, the sensor provides a measure of the weld pool size (diameter at surface) exact location on the part relative to prior features, and the temperature at the weld pool and just ahead of the weld pool; then the laser power level and focus point and position are adjusted by the control system to limit the error between the measured values from the sensors and the desired values based on prior experience, model based calculations or other means. In one such embodiment, the size of the weld pool is estimated indirectly based on the conductivity variation just before and after the weld pool, including the time varying nature of these values. In one such embodiment these values include variations in both the sensor scan direction and along the array (transverse to the scan direction). In another such embodiment multiple frequencies are used to provide depth information that enables further estimation of weld pool condition using an eddy current array such as the MWM-Array. In another embodiment a more direct estimation of the weld pool dimensions is provided by locating the sensing elements close enough to the weld pool and exciting inducing eddy currents that pass through the weld pool. In one such embodiment a numerical model or other simplified model is used to estimate the conductivity at and radially outward from the center of the weld pool and a multivariate inverse method is used to estimate the weld pool diameter and center point conductivity, where the conductivity is then used to estimate the weld pool temperature given the diameter estimation.

Additional sensors 260 may provide remote sensing using optical, thermographic or other means. Sensor 230 and additional sensors 260 may be used for control and/or also for quality assessment such as for geometry measurements, coordination of sensor motion, or surface roughness or powder assessments.

Attention is now turned to FIGS. 3A-3C for discussion of some embodiments of sensor 230. In these figures the sense element arrays are shown having 4 rectangular elements, however it should be appreciated that any suitable number of elements or element shape may be present in the arrays. Also the leads of the drive winding and sense element array, whether shown or not shown, may be configured for connection to suitable electronics for excitation and measurement of the respective sensor.

In FIG. 3A sensor 310 is an eddy current array sensor having a drive winding 311 and a sense element array 313. Sensor 310 has an open space 315 through which a laser beam may pass. Drive winding 311 may have a linear portion adjacent to open space 315 as shown. The elements of array 313 may be parallel to the linear portion of drive winding 312.

FIG. 3B shows sensor 320 which has a drive winding 321 and sense element array 323. Drive winding 321 has two lateral loops. In the specific embodiment shown the loops are rectangular. For clarity the vias (or other electrical connectors for connecting through multiple layers) and leads of drive winding 321 have not been shown; the two loops may be connected together such that an electrical current passing through the two adjacent center portions are in the same direction at the same time as indicated by the arrows. It should be appreciated that while closed loops and drive or sense “rectangles” are referenced or shown, these are current carrying paths that begin and terminate at an instrument for measurement (e.g., instrument 110). Again an open space 325 allows a laser beam to pass through the sensor. In some embodiments open space 325 is within one of the loops of drive winding 321. In some embodiments sense element array is within or partially within one of the loops of drive winding 321.

FIG. 3C shows sensor 330 which has a drive winding 331, sense element array 332, and sense element array 333. An open space 335 allows a laser beam to pass through sensor 330. Sense element array 322 is a distance D1 away from a linear portion of drive winding 331. Sense element array 323 is a distance D2 away from a linear portion of drive winding 331. Distances D1 and D2 may be the same or different distances. In the embodiment shown, D1 is less than D2.

In some embodiments of system 200 sensor 230 or additional sensor 260 is scanned over the surface of powder bed 201 to provide layer-by-layer quality assessment (potentially detecting defects) or for real-time process control. In some embodiments additional sensor 260 includes a sensor configured with rake/roller 210 to perform such a scan as part of the powder layer deposition process. For layer-by-layer inspection of a part during AM processing a sensor provides a scan of the surface before or after a layer is added. In one such embodiment sensor measurements are taken at two simultaneous frequencies to measure the conductivity, thickness and lift-off relative to a deposited layer after deposition. The estimated conductivity is used to assess quality and detect defects such as cracks, voids, metallurgical variations, or porosity; the lift-off estimate is used to assess local roughness, surface breaking pores, and geometric variations such as for edge location (sometimes using a databases of responses created off line for anticipated features). A layer thickness measurement may be used to verify the quality and consistency of the deposition or to control the geometry as part of the build processing.

In another such embodiment three frequencies are used to add the capability to assess the bond integrity between the most recently deposited layer and the prior layer, to provide more information about particle size distributions for the powder, to improve defect detection in the part or for identification of splatter in the powder ahead of the processing. Each of the above methods can be used between depositions in coordination with the motion of the rake or roller or by some other means, or during the process.

For real-time control during the process sensor 230 may lead, follow or straddle the melt pool. If sensor 230 is straddling the melt pool and is a MWM-Array type sensor (having a linear drive portion and linear sensor array) then the row of sensing elements and at least one linear drive conductor will be on opposite sides of the melt pool. This enables the MWM-Array response to be sensitive to the melt pool dimensions. In one such embodiment a library of sensor responses is recorded for a range of melt pool conditions including geometry with or without an alternative sensing modality (such as optical) for providing the melt pool actual dimensions. This library is used for both training of the data analysis or for real-time processing of data for control. By using the library to estimate the melt pool dimensions in real-time the process parameters can be adjusted to maintain melt pool dimensions and conditions as close as possible to the desired goal.

In one embodiment of layer-by-layer quality assessment, at least one MWM-Array is integrated with a roller or rake either before the rake, after the rake or both. The MWM-Array that is ahead of the rake provides inspection of the part quality. The array after the rake provides assessment of the powder condition. In each such embodiment at least two frequencies are used to estimate at least three properties (such as conductivity, thickness and liftoff) for the added layer or the powder and relate the measured properties to conditions or defects of interest for quality assessment or adjustment of processing parameters. In one such embodiment, a 3-dimensional representation of the part is built up in digital archived formatted to enable local and global assessments of quality. In one such embodiment, the global conductivity trends are used to evaluate the integrity of the process and the fabricated part including near complex geometric features. In one such embodiment the defect response is analyzed only along the two dimensional scanned surface using shaped filters as demonstrated in the past by the inventors. In a new embodiment spatial signatures are used on surfaces that are out of the plane of the processing to improve the detection of defects or to enable geometric feature dimensional assessment out of the plane of the fabricated layers. In one such embodiment conductivity variations along selected planes within the part are displayed to provide a visual assessment of metallurgical or other material condition. In one such embodiment the measured conductivity along the internal surfaces of a cavity such as a hole are imaged and displayed for visual quality assessment with a revealing color scale to aid the operator. In another such embodiment digital image processing tools are used to analyze patterns in the conductivity and to compare these patterns to acceptable and unacceptable patterns for quality assessment or defect detection. In one embodiment of all the methods described the sensor data is taken for one or more test parts during slower processing and used to improve processing at a faster speed on subsequent components. In another such embodiment, some sensor data is only taken at prescribed increments during processing. In one such embodiment sensor data is taken every 10^{th} layer added to the part and the sensor is retracted in between to avoid slowing down the processing.

MWM-Array sensing formats are described that include single rectangle (e.g., sensors 310 and 330) and dual rectangle (e.g., sensor 320) drive constructs. In one embodiment for in process real-time monitoring of the melt pool a window is cut out of the sensor footprint to accommodate the laser sintering or e-beam welding and avoid damage to the sensor. The sensor is in a plane located at an approximately constant liftoff above the most recently fabricated layer and the powder so that this liftoff is within the sensitive range of the sensor, but far enough away as to not interfere with the process and to avoid damage to the sensor. In one such embodiment the distance between the drive and sensing elements is at least four times the liftoff. In other such embodiments the drive sense gap is much larger than the liftoff. This will impact the resolution of the imaging and effective footprint of the individual sensing elements.

In one embodiment two sensing element rows are included ahead of and behind a single drive rectangle with a cutout window inside the rectangle to accommodate processing. In one such embodiment the leading row of sensing elements assesses the powder condition and its temperature and the trailing set of elements assesses the condition of the added layer and its temperature, while a combination of the leading and trailing responses provides a measure of the melt pool dimensions, temperature or other condition. In some embodiments of fabricated part eddy current sensor temperature measurement a module relates the conductivity of the added layer or of multiple previously added layers to temperature. For metals this relationship is known to be linear up to a certain temperature, however nonlinear relationships can be stored and used for such estimation for the melt pool. For the solidified metal layer the relationship between conductivity and temperature can be a simple correlation table that is used by the software to provide a real time estimation of temperature following the process and ahead of the process. In one such embodiment the sensor provides a measure of the recently applied powder temperature and sees through the powder to measure the temperature of the prior solidified layer. In one such embodiment a multiple frequency model based multivaratiate inverse method is used. In one method for estimating powder temperature at least three relatively high frequencies (above 1 MHz with the range depending on the type of metal, being higher for less conducting metals) are used to estimate the powder properties including temperature using prior measurements on such powders at varied temperatures to train the method. Training can be simply a module for correlating the ratio of conductivity measurements at two frequencies or another function with prior measurements to estimate properties, or another module for such estimation may be used.

In one embodiment, the drive rectangle and sensing array are located on opposite sides of the melt pool so that the sensing element responses vary with the condition of the melt pool. In one such embodiment the drive to sensing array gap is adjustable depending on the desired image resolution and processing conditions. In one such embodiment the drive and sensing array are on different substrates to enable easy adjustment of the drive to sense distance.

In one embodiment the MWM-Array has at least two rectangular drives. In one such embodiment a window is cut within one drive and a sensing array is within the same drive loop. In one such embodiment the sensing array is located halfway between the central drive conductor and the return conductor to provide the smallest effective sensing footprint and accommodate the largest possible liftoff. In one embodiment, at least three drive rectangles are incorporated and more than one laser is used to speed up the processing in a coordinated manner.

In one embodiment the powder is analyzed using multiple frequency methods with at least three simultaneous frequencies. In one such embodiment, additional data is taken ahead of the processing with the MWM-Array stationary and at least 6 frequencies. In one embodiment the multiple frequency data is used to assess particle size using a library of prior responses. In one such embodiment the diamagnetic complex permeability is used as an abstract representation of the powder-to-magnetic field interaction with a model that enables the estimation of particle size distribution, detection of clumping, detection of splatter, or improved estimation of powder temperature and correction for the liftoff relative to the powder. In one embodiment for any MWM-Array or eddy current sensor format one or more frequencies are used to estimate the powder height locally. In one such embodiment this liftoff estimation is used to adjust the processing to accommodate variations in powder height.

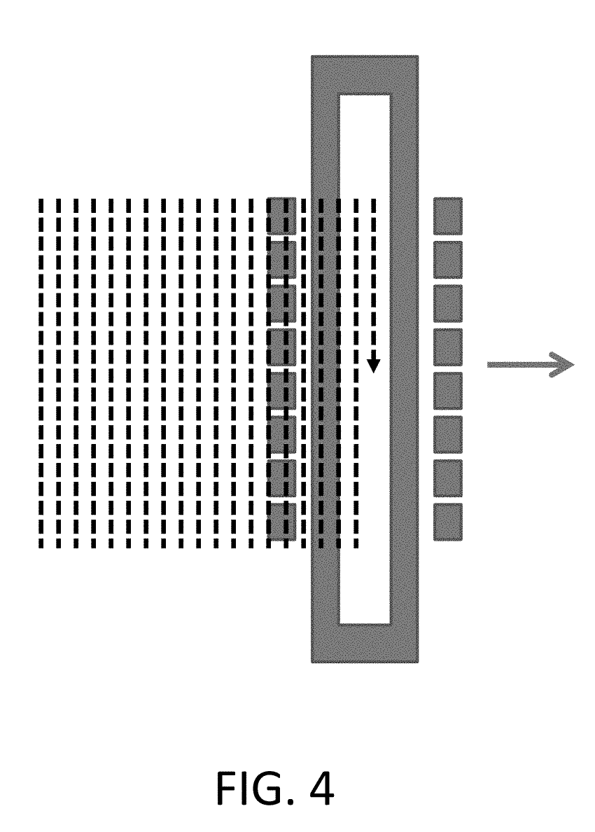

In one embodiment, shown in FIG. 4, the sensor extends across the majority and possibly all of the powder bed. In one such embodiment the laser sintering pattern is a series of linear motions across the bed with the sensor stationary during the linear crossing of the bed by the laser during AM processing. In one such embodiment the sensor then moves with the same small increments in coordination with the laser between processing passes. The sensor moves in the direction perpendicular to the longer winding segment orientation and the laser motion during processing is in the direction perpendicular to the scan direction (i.e. in the same direction as the longer winding segment orientation). This coordinated motion and configuration is for real-time process monitoring and control.

In one such embodiment represented by the block diagram sensor data is recorded only before and after adding a new layer, but not during processing. In one such embodiment two MWM-Arrays are integrated with the rake or roller one leading and one trailing the rake or roller. The leading MWM-Array provides a measure of the part properties (such as conductivity and liftoff to determine metallurgical condition, defect presence or surface roughness for example) at one or more frequencies and the trailing MWM-Array provides a measure of the powder height, condition and temperature or other such properties. On one such embodiment the sensor data is provided to the laser control system or other process control system to adjust the processing given the sensor data. In one such embodiment the laser path is adjusted based on both the prior layer properties and dimensions as measured by the sensor and the powder properties as measured by providing an appropriate control action. In this embodiment that does not use real time sensing data the laser control actions are determined for the entire next layer processing. In another such embodiment real-time sensing data is used during the process to adjust the laser and other processing parameters in real-time in response to the sensor data.

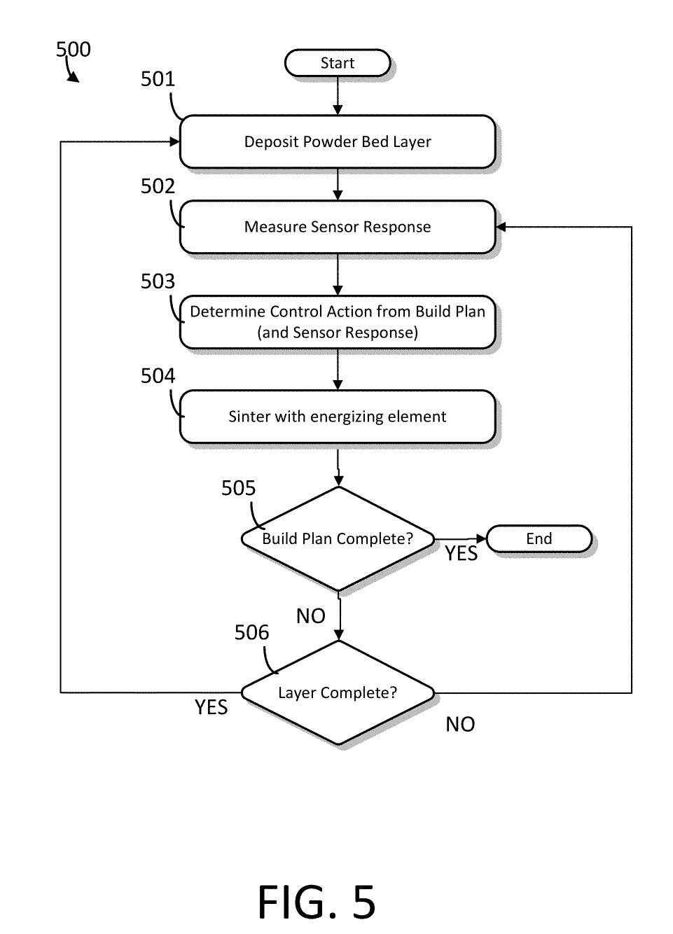

FIG. 5 is a flow diagram that shows a method 500 of an in situ additive manufacturing process. At step 501 a powder bed layer is deposited. At step 502 a sensor response is measured. At step 503 a control action is determined from the build plan and sensor response (if available). At step 504 an energizing element is used to sinter the powder in accordance with the control action. At step 505 a determination is made if the build plan is complete; if so method 500 ends, otherwise method 500 continues to step 506. At step 506 a determination is made if the layer is complete. If “NO”, method 500 continues to step 502. If “YES” method 500 continues to step 501.

Having thus described several aspects of at least one embodiment of this invention, it is to be appreciated that various alterations, modifications, and improvements will readily occur to those skilled in the art.

Such alterations, modifications, and improvements are intended to be part of this disclosure, and are intended to be within the spirit and scope of the invention. Accordingly, the foregoing description and drawings are by way of example only.

The above-described embodiments of the present invention can be implemented in any of numerous ways. For example, the embodiments may be implemented using hardware, software or a combination thereof. When implemented in software, the software code can be executed on any suitable processor or collection of processors, whether provided in a single computer or distributed among multiple computers.

Further, it should be appreciated that a computer may be embodied in any of a number of forms, such as a rack-mounted computer, a desktop computer, a laptop computer, or a tablet computer. Additionally, a computer may be embedded in a device not generally regarded as a computer but with suitable processing capabilities, including a Personal Digital Assistant (PDA), a smart phone or any other suitable portable or fixed electronic device.

Also, a computer may have one or more input and output devices. These devices can be used, among other things, to present a user interface. Examples of output devices that can be used to provide a user interface include printers or display screens for visual presentation of output and speakers or other sound generating devices for audible presentation of output. Examples of input devices that can be used for a user interface include keyboards, and pointing devices, such as mice, touch pads, and digitizing tablets. As another example, a computer may receive input information through speech recognition or in other audible format.

Such computers may be interconnected by one or more networks in any suitable form, including as a local area network or a wide area network, such as an enterprise network or the Internet. Such networks may be based on any suitable technology and may operate according to any suitable protocol and may include wireless networks, wired networks or fiber optic networks.

Also, the various methods or processes outlined herein may be coded as software that is executable on one or more processors that employ any one of a variety of operating systems or platforms. Additionally, such software may be written using any of a number of suitable programming languages and/or programming or scripting tools, and also may be compiled as executable machine language code or intermediate code that is executed on a framework or virtual machine.

In this respect, the invention may be embodied as a computer readable medium (or multiple computer readable media) (e.g., a computer memory, one or more floppy discs, compact discs, optical discs, magnetic tapes, flash memories, circuit configurations in Field Programmable Gate Arrays or other semiconductor devices, or other tangible computer storage medium) encoded with one or more programs that, when executed on one or more computers or other processors, perform methods that implement the various embodiments of the invention discussed above. The computer readable medium or media can be transportable, such that the program or programs stored thereon can be loaded onto one or more different computers or other processors to implement various aspects of the present invention as discussed above.

In this respect, it should be appreciated that one implementation of the above-described embodiments comprises at least one computer-readable medium encoded with a computer program (e.g., a plurality of instructions), which, when executed on a processor, performs some or all of the above-discussed functions of these embodiments. As used herein, the term “computer-readable medium” encompasses only a computer-readable medium that can be considered to be a machine or a manufacture (i.e., article of manufacture). A computer-readable medium may be, for example, a tangible medium on which computer-readable information may be encoded or stored, a storage medium on which computer-readable information may be encoded or stored, and/or a non-transitory medium on which computer-readable information may be encoded or stored. Other non-exhaustive examples of computer-readable media include a computer memory (e.g., a ROM, a RAM, a flash memory, or other type of computer memory), a magnetic disc or tape, an optical disc, and/or other types of computer-readable media that can be considered to be a machine or a manufacture.

The terms “program” or “software” are used herein in a generic sense to refer to any type of computer code or set of computer-executable instructions that can be employed to program a computer or other processor to implement various aspects of the present invention as discussed above. Additionally, it should be appreciated that according to one aspect of this embodiment, one or more computer programs that when executed perform methods of the present invention need not reside on a single computer or processor, but may be distributed in a modular fashion amongst a number of different computers or processors to implement various aspects of the present invention.

Computer-executable instructions may be in many forms, such as program modules, executed by one or more computers or other devices. Generally, program modules include routines, programs, objects, components, data structures, etc. that perform particular tasks or implement particular abstract data types. Typically the functionality of the program modules may be combined or distributed as desired in various embodiments.

Also, data structures may be stored in computer-readable media in any suitable form. For simplicity of illustration, data structures may be shown to have fields that are related through location in the data structure. Such relationships may likewise be achieved by assigning storage for the fields with locations in a computer-readable medium that conveys relationship between the fields. However, any suitable mechanism may be used to establish a relationship between information in fields of a data structure, including through the use of pointers, tags or other mechanisms that establish relationship between data elements.

Various aspects of the present invention may be used alone, in combination, or in a variety of arrangements not specifically discussed in the embodiments described in the foregoing and is therefore not limited in its application to the details and arrangement of components set forth in the foregoing description or illustrated in the drawings. For example, aspects described in one embodiment may be combined in any manner with aspects described in other embodiments.

Also, the invention may be embodied as a method, of which an example has been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

For the purposes of describing and defining the present disclosure, it is noted that terms of degree (e.g., “substantially,” “slightly,” “about,” “comparable,” etc.) may be utilized herein to represent the inherent degree of uncertainty that may be attributed to any quantitative comparison, value, measurement, or other representation. Such terms of degree may also be utilized herein to represent the degree by which a quantitative representation may vary from a stated reference (e.g., about 10% or less) without resulting in a change in the basic function of the subject matter at issue. Unless otherwise stated herein, any numerical values appeared in this specification are deemed modified by a term of degree thereby reflecting their intrinsic uncertainty.

Use of ordinal terms such as “first,” “second,” “third,” etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

Also, the phraseology and terminology used herein is for the purpose of description and should not be regarded as limiting. The use of “including,” “comprising,” or “having,” “containing,” “involving,” and variations thereof herein, is meant to encompass the items listed thereafter and equivalents thereof as well as additional items.

What is claimed is:

1. An additive manufacturing (AM) system for producing an AM part, the system comprising:
a laser;
a build platform;
a sensor with a drive winding having a linear portion and a linear array of sense windings a constant distance from the linear portion of the drive winding;
a sensor positioning system to position the sensor between the laser and the build platform;
an instrument to monitor a response of the sensor during an additive manufacturing process; and
a control system configured to control the laser and the sensor positioning system based at least in part on the response of the sensor.

2. The AM system of claim 1 wherein
the sensor has an open space between the linear portion of the drive winding and the linear array of sense windings, and
the control system is configured to control the laser and the sensor positioning system to focus the laser in the open space during the additive manufacturing process.

3. The AM system of claim 1 wherein
each of the sense windings in the linear array have a rectangular winding portion and leads thereto, and
the instrument excites a current at a frequency and measures the response of the sensor at each sense winding in the linear array at said frequency.

4. The AM system of claim 1 wherein
the linear array of sense windings is a first linear array and the sensor further comprises a second linear array of sense windings at a second constant distance from the linear portion of the drive winding, and
the instrument measures the response of the sensor at each sense winding in the first linear array and each sense winding in the second linear array.

5. The AM system of claim 1 further comprising an analysis module to determine, based at least in part on the response of the sensor, a quality of the AM part.

6. The AM system of claim 5 further comprising an optimal sensor, wherein the analysis module determines the quality of the AM part based at least in part on a response of the optical sensor.

7. The AM system of claim 1 wherein the control system determines a property of the melt pool from the sensor response and controls the laser and the sensor positioning system based at least in part on the property of the melt pool.

8. The AM system of claim 7 wherein the property is temperature.

9. A method of additively manufacturing (AM) an AM part, the method comprising:
providing a powder bed on a build platform;
providing a sensor in a noncontact mode above the powder bed, the sensor having a drive winding with a linear portion and a linear array of sense windings a constant distance from the linear portion of the drive winding;
directing a laser at a location on the powder bed through an open space in the sensor;
exciting a current at a frequency in the drive winding;
measuring a response of the sensor to the current; and
redirecting the laser and controlling the position of the sensor based at least in part on the response of the sensor.

10. The method of claim 9 wherein providing the powder bed comprises depositing a plurality of powder layers, the powder layers including a surface layer and a subsurface layer, the method further comprising:
determining from the response of the sensor a first property of the surface layer and a second property of the subsurface layer in the powder bed.

11. The method of claim 9 wherein
providing the powder bed comprises depositing a plurality of powder layers, the powder layers including a surface layer, and
the penetration depth at the frequency of the drive current is greater than a thickness of the surface layer but less than three times the thickness of the surface layer.

12. The method of claim 9 wherein
providing the powder bed comprises depositing a plurality of powder layers, the powder layers including a surface layer and a subsurface layer,
the frequency is a first frequency and the current is also excited at a second frequency,
the response of the sensor is measured at both the first and second frequencies, and the method further comprises
determining at least three properties of the powder bed, at least one of the properties being of the surface layer and at least another one of the properties being of the subsurface layer.

13. The method of claim 12, wherein the at least three properties comprise a liftoff of the sensor from the powder bed, a conductivity of the surface layer, and a conductivity of the subsurface layer.

14. An additive manufacturing (AM) system for producing an AM part, the system comprising:
an energizing element for sintering an AM feed stock;
an eddy current sensor;
an instrument to monitor a response of the eddy current sensor during sintering; and
a control system configured to control the energizing element based at least in part on the response of the eddy current sensor.

15. The system of claim 14 wherein the eddy current sensor is an eddy current array sensor having a drive winding with a linear portion and a linear array of sense windings a constant distance from the linear portion of the drive winding.

16. The system of claim 15, further comprising a sensor positioning system for positioning the eddy current array sensor, wherein the control system additionally controls a position of the sensor positioning system based at least in part on the response of the eddy current array sensor.

17. The system of claim 14 wherein the energizing element is a laser.

18. The system of claim 14 wherein the energizing element is an electron beam.

19. The system of claim 14 further comprising:
a build platform; and
a powder distributor for distributing a layer of powder over the build platform, wherein the eddy current sensor is an eddy current sensor array mechanically attached to the powder distributor.
